(19) United States
(12) Patent Application Publication
(10) Pub. No.: US 2010/0007397 A1
(43) Pub. Date: Jan. 14, 2010

(54) Delay line circuit for generating a fixed delay

(75) Inventors: Shengyuan Zhang, Shanghai (CN); Yong Wang, Shanghai (CN); Yanbo Wang, Shanghai (CN)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Integrated Device Technology, Inc.

(21) Appl. No.: 12/218,457

(22) Filed: Jul. 11, 2008

(51) Int. Cl. H03H 11/26; H03K 3/011; G05F 1/00

(52) U.S. Cl. 327/262; 327/512; 327/513; 327/539

(57) ABSTRACT

A delay line circuit is provided. The delay line circuit includes a reference voltage generating circuit that generates a reference voltage, the reference voltage having a positive temperature coefficient. The delay line circuit also includes a voltage regulating circuit that generates a regulated voltage in response to the generated reference voltage as an input, and a delay chain circuit coupled to the voltage regulator to receive the regulated voltage, the delay chain circuit outputting a delay signal. In an embodiment consistent with the present invention, the reference voltage generating circuit includes a bandgap reference voltage circuit. In another embodiment consistent with the present invention, the reference voltage generating circuit includes a proportional to absolute temperature (PTAT) circuit.

### BACKGROUND

1. Technical Field

Embodiments consistent with the present invention are related to a circuit for generating a delay, and, in particular, a delay line circuit for generating a fixed delay which does not rely on a stable reference clock.

2. Discussion of Related Art

Due to the great improvement of both design techniques and process technology, the speed of IC (integrated circuit) devices has increased considerably. A variety of IC chips have high clock rates and as a result have precise timing requirements. The next generation memory chips, for example, memory chips which may adhere to the JEDEC DDR2 and DDR3 standards, must be able to communicate with other chips at increasingly faster speeds. The timing between applying a read signal at one clock speed and sampling, at another clock speed, the data output in response to the read signal is precisely controlled. Accordingly, to facilitate communications between chips having different clock speeds, a delay is generated, delaying a chip operating at a higher speed by a predetermined amount so that it can communicate with a chip operating at a lower speed.

In some system applications, an output signal may be required to have a fixed delay from input to output. Systems may typically achieve this using a stable reference clock. However, due to increased integration and other considerations, some systems do not use a stable reference clock, which may make it difficult to generate a fixed delay. Without a stable reference clock, the delay of delay line circuit typically has a large variation with power supply and temperature. Voltage regulators may be used to compensate for variations attributed to the power supply because a voltage regulator outputs a voltage which is typically stable and independent of the power supply. However, as the temperature of the circuit increases, the delay generated by the delay line circuit will also increase, often linearly.

Accordingly, there is a need for a delay line circuit capable of generating a fixed delay.

### SUMMARY

Consistent with the present invention, there is provided a delay line circuit that includes a reference voltage generating circuit that generates a reference voltage, the reference voltage having a positive temperature coefficient; a voltage regulating circuit that generates a regulated voltage in response to the generated reference voltage as an input; and a delay chain circuit coupled to the voltage regulator to receive the regulated voltage, the delay chain circuit outputting a delay signal.

Consistent with the present invention, there is also provided a bandgap voltage reference circuit for generating a reference voltage, that includes a plurality of current sources, each of the current sources receiving a supply voltage as an input, and each of the current sources outputting a current through a resistance; a first transistor coupled to a first current source of the plurality of current sources, the first transistor receiving a first current as an input; a second transistor coupled to a second current source of the plurality of current sources, the second transistor receiving a second current as an input; and an amplifier coupled to the first and second transistors and the current sources, wherein the generated reference voltage has a positive temperature coefficient.

A proportional to absolute temperature (PTAT) circuit for generating a reference voltage having a positive temperature coefficient is also provided. The PTAT circuit comprises a plurality of current sources, each of the current sources receiving a supply voltage as an input, and each of the current sources outputting a current; a first transistor coupled to a first current source of the plurality of current sources, the first transistor receiving a first current as an input; a second transistor coupled to a second current source of the plurality of current sources, the second transistor receiving a second current as an input; and an amplifier coupled to the first and second transistors and the current sources, wherein the generated reference voltage has a positive temperature coefficient.

Consistent with embodiments of the present invention, there is also provided a method of fixing a delay signal output from a delay line circuit, that includes generating a reference voltage using a voltage generator having a positive temperature coefficient; supplying the reference voltage to a delay chain, the delay chain outputting a delay signal having a predetermined delay, the predetermined delay being dependent on at least a level of the reference voltage and a temperature of the delay line circuit; and changing the reference voltage in response to a change in the temperature, such that the changed reference voltage compensates for a change in the delay due to the change in the temperature.

It is to be understood that both the foregoing general description and the following detailed description are exemplary and explanatory only and are not restrictive of the invention. Further embodiments and aspects of the invention are described with reference to the accompanying drawings, which are incorporated in and constitute a part of this specification.

### BRIEF DESCRIPTION OF THE DRAWINGS

FIG. 1 is a block diagram of a delay line circuit consistent with embodiments of the present invention.

FIG. 2 is a diagram of a bandgap voltage reference consistent with embodiments of the present invention.

FIG. 3 is a diagram of a proportional to absolute temperature (PTAT) circuit consistent with embodiments of the present invention.

### DETAILED DESCRIPTION

Reference will now be made in detail to the embodiments consistent with the present invention, examples of which are illustrated in the accompanying drawings. Wherever possible, the same reference numbers will be used throughout the drawings to refer to the same or like parts.

In some embodiments, a delay line circuit for providing a fixed delay, which is independent of a power supply and temperature, and which is generated without reference clock, is provided. As noted above, problems that may arise when generating a delay are variations of the delay resulting from a variation of a power supply and the temperature of the circuit. In typical delay line circuits, as the temperature of the circuit increases, the delay will also increase. Moreover, as the supplied power increases, the delay will decrease. Accordingly, a delay line circuit consistent with the present invention may use the relationship between the temperature of the circuit and the power supply to actively compensate for the temperature of a circuit by varying the power supply, in some embodiments creating a delay line circuit wherein the delay is independent of, and will not change in response to, a changing power supply and a changing temperature.

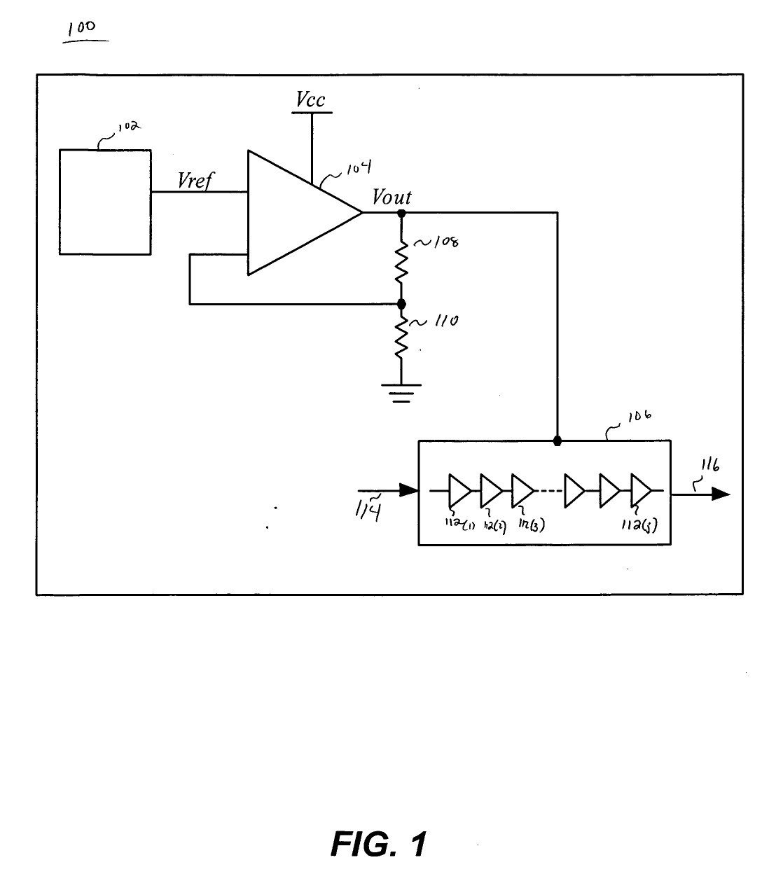

FIG. 1 shows a block diagram of an embodiment of a delay line circuit 100 that is consistent with aspects of the present invention. As shown in FIG. 1, delay line circuit 100 includes a reference voltage generating circuit 102 coupled to a voltage regulating circuit 104. Voltage regulating circuit 104 is coupled to a delay chain circuit 106. As shown in FIG. 1, delay line circuit 100 also includes a first resistor 108 and second resistor 110 coupled between an output terminal of voltage regulating circuit 104 and ground. The voltage across resistor 108 is fed back to voltage regulating circuit 104 as an input into voltage regulating circuit 104. Delay line circuit 100 also includes a second resistor 110, which is coupled between first resistor 108 and ground.

As shown in FIG. 1, a reference voltage V_{ref} is output to voltage regulating circuit 104 by reference voltage generator 102. A common collector voltage, or power supply voltage V_{cc}, is also input into voltage regulating circuit 104. Voltage regulating circuit 104 outputs a regulated voltage Vₒᵤₜ, which is input into delay line 108. Delay chain circuit 106, which may comprise a plurality of serially-connected delay cells 112(1) . . . 112(j), receives an input signal 114, and outputs a delay signal 116 having a predetermined delay. In accordance with aspects of the present invention, the delay signal 116, and consequently, the predetermined delay, depend on regulated voltage Vₒᵤₜ.

As shown in FIG. 1, regulated voltage Vₒᵤₜ, is dependent on reference voltage V_{ref} and the resistances of resistors 108 and 110. Consistent with embodiments of the present invention, resistors 108 and 110 have fixed resistance values of R₁₀₈ and R₁₁₀, respectively. Accordingly, Vₒᵤₜ, is equal to:

$${V}_{out} = {V}_{ref } \cdot ( 1 + \frac{{R}_{108}}{{R}_{110}} ) .$$

Because regulated voltage Vₒᵤₜ, is dependent on reference voltage V_{ref}, the delay signal 116 output by delay chain circuit 106 is also influenced by reference voltage V_{ref}, wherein the delay decreases as V_{ref} increases.

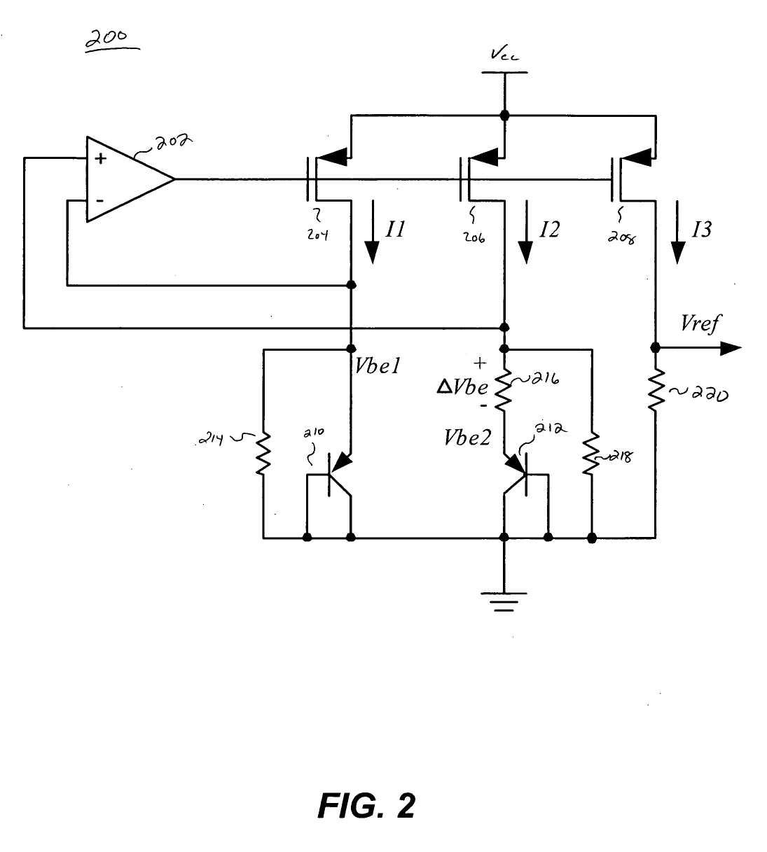

FIG. 2 is a diagram of a bandgap voltage reference circuit 200, consistent with embodiments of the present invention. In accordance with aspects of the present invention, bandgap voltage reference circuit 200 generates reference voltage V_{ref}, and can be utilized as reference voltage generating circuit 102 in FIG. 1. Bandgap voltage reference circuit 200 includes an amplifier 202 coupled to current sources 204, 206, and 208. Consistent with embodiments of the present invention, current sources 204, 206, and 208 may comprise n-channel MOSFETs, as shown in FIG. 2. Power supply voltage V_{cc} is input into current sources 204, 206, and 208, and currents I1, I2, and I3 are respectively output from current sources 204, 206, and 208. In accordance with aspects of the present invention, the ratio of currents I1, I2, and I3 is 1:1:m, wherein m is a positive integer, such that I1=I2, and I3=m·I1. As discussed in more detail below, integer m may be used as a tuning parameter such that reference voltage V_{ref} may be adjusted, or tuned, to have a predetermined level which, in turn, may have a predetermined influence on the delay of delay signal 116.

Bandgap voltage reference circuit 200 also includes transistors 210 and 212. Consistent with the present invention, transistors 210 and 212 may be pnp transistors having a ratio of current densities of 1:n, n being a positive integer. Integer n may also be used as a tuning parameter such that reference voltage V_{ref} may be adjusted, or tuned, to have a predetermined level which, in turn, may have a predetermined influence on the delay of delay signal 116. Consistent with the present invention, transistor 212 may be coupled to ground.

In accordance with aspects of the present invention, a resistor 214 having a resistance of R₂₁₄ may be coupled between a base of transistor 210 and current source 204, a resistor 216 having a resistance of R₂₁₆ may be coupled between current source 206 and the emitter of transistor 212, and a resistor 218 having a resistance of R₂₁₈ may be coupled between current source 206 and the base of transistor 212. Bandgap reference voltage circuit 200 may also include resistor 220 having a resistance of R₂₂₀ coupled to current source 208 at the output of bandgap voltage reference circuit 200.

In accordance with aspects of the present invention, transistor 210 has a base-emitter voltage of V_{be1} and transistor 212 has a base-emitter voltage of V_{be2}. Across resistor 216 a differential base-emitter voltage is created ΔV_{be}, which is equal to V_{be1}−V_{be2}. Moreover, as shown in FIG. 2, amplifier 202 is connected so as to be in a feedback loop that causes the voltages across resistor 214 and resistor 218 to be the same. Based on this, the reference voltage V_{ref} output from bandgap voltage reference circuit may be calculated as follows:

$${V}_{ref} = ( \frac{Δ {V}_{be}}{{R}_{216}} + \frac{{Δ}_{be 1}}{{R}_{218}} ) \cdot m \cdot {R}_{220} .$$

Using the Ebers-Moll equation, ΔV_{be} is determined to be the thermal voltage of the circuit, V_{T} multiplied by the natural logarithm of the ratio of current densities between transistors 210 and 212, such that the equation may be rewritten as:

$${V}_{ref} = ( \frac{Δ {V}_{T} \cdot {log}_{e} n}{{R}_{216}} + \frac{{V}_{be 1}}{{R}_{218}} ) \cdot m \cdot {R}_{220} ,$$

wherein thermal voltage

$${V}_{T} = \frac{kT}{q} ,$$

k being Boltzmann's constant (1.38×10⁻²³ joules/° K), T being the temperature of the circuit in degrees Kelvin, and q being the electron charge (1.60×10⁻¹⁹ coulombs).

As noted above, due to temperature increases, a delay signal 116 output by delay chain circuit 106 will increase, the increase in delay being linear with the change in temperature. However, as shown by the above equations, because reference voltage V_{ref} is dependent on temperature T, reference voltage V_{ref} will also increase linearly as the temperature increases, provided that V_{ref} has a positive temperature coefficient. Moreover, as V_{ref} increases, Vₒᵤₜ also increases, which will reduce the delay of delay signal 116. Therefore, n is chosen such that

$$\frac{{V}_{T} \cdot {log}_{e} n}{{R}_{216}} > \frac{{V}_{be 1}}{{R}_{218}} ,$$

so that V_{ref} has a positive temperature coefficient, and the increased V_{ref} will compensate for any delay increases caused by increasing temperature. Delay line circuit 100 using bandgap voltage reference circuit 200 may thus produce a delay signal 116 that is substantially independent of temperature effects, as bandgap voltage reference circuit 200 automatically compensates for any temperature-related delay changes. Moreover, consistent with the present invention, reference voltage V_{ref} may have a high power supply rejection ratio.

Referring back to FIG. 1, regulated voltage Vₒᵤₜ, may be rewritten as:

$${V}_{out} = ( \frac{{V}_{T} \cdot {log}_{e} n}{{R}_{216}} + \frac{{V}_{be 1}}{{R}_{218}} ) \cdot m \cdot {R}_{220} \cdot ( 1 + \frac{{R}_{108}}{{R}_{110}} )$$

As can be seen by the above equations, reference voltage Vₒᵤₜ, may be tuned by choosing the values of ratios n and m, and resistances R₁₀₈, R₁₁₀, R₂₁₆, R₂₁₈, and R₂₂₀ to output a regulated voltage Vₒᵤₜ, having a specific delay. Vₒᵤₜ, may further be tuned such that the linear change in Vₒᵤₜ, from a change in temperature is sufficient to offset the change in delay resulting from the same change in temperature. Accordingly, delay line circuit 100 using bandgap voltage reference circuit as a reference voltage generating circuit 102 may allow for a highly customizable circuit for generating a delay wherein reference voltage V_{ref} is increased by an amount which is proportional to the increase in delay, to automatically compensate for temperature effects.

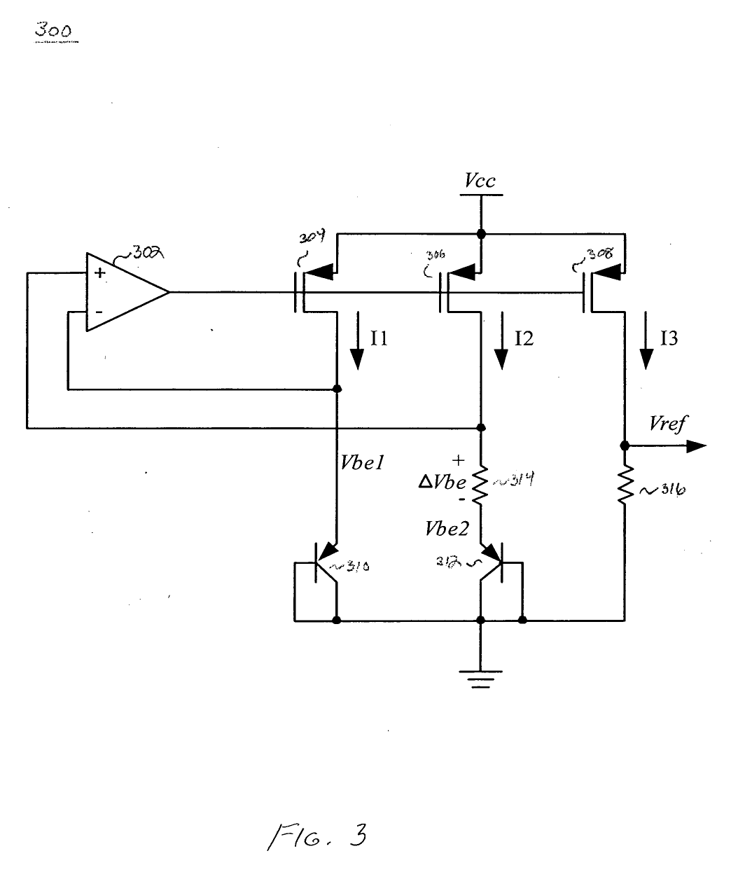

In another embodiment consistent with the present invention, voltage reference circuit 102 may comprise a proportional to absolute temperature (PTAT) circuit 300 as shown in FIG. 3. FIG. 3 is a diagram of a PTAT circuit 300 consistent with embodiments of the present invention. PTAT circuit 300 includes an amplifier 302 coupled to current sources 304, 306, and 308. Consistent with embodiments of the present invention, current sources 304, 306, and 308 may comprise n-channel MOSFETs, as shown in FIG. 3. Power supply voltage V_{cc} is input into current sources 304, 306, and 308, and currents I1, I2, and I3 are respectively output from current sources 304, 306, and 308. In accordance with aspects of the present invention, the ratio of currents I1, I2, and I3 is 1:1:m, wherein m is a positive integer, such that I1=I2, and I3=m·I1. The integer m is used as a tuning parameter such that reference voltage V_{ref} may be adjusted, or tuned, to have a predetermined level which, in turn, may have a predetermined influence on the delay of delay signal 116.

PTAT circuit 300 also includes transistors 310 and 312. Consistent with the present invention, transistors 310 and 312 may be pnp transistors having a ratio of current densities of 1:n, n being a positive integer. The integer n may also be used as a tuning parameter such that reference voltage V_{ref} may be adjusted, or tuned, to have a predetermined level which, in turn, may have a predetermined influence on the delay of delay signal 116. Consistent with the present invention, transistor 312 may be coupled to ground.

In accordance with aspects of the present invention, a resistor 314 having a resistance of R₃₁₄ may be coupled between current source 306 and the emitter of transistor 312, and a resistor 316 having a resistance of R₃₁₆ may be coupled to current source 308 at the output of PTAT circuit 300.

In accordance with aspects of the present invention, transistor 310 has a base-emitter voltage of V_{be1} and transistor 312 has a base-emitter voltage of V_{be2}. Across resistor 314 a differential base-emitter voltage ΔV_{be} is created, which is equal to V_{be1}−V_{be2}. Moreover, as shown in FIG. 3, amplifier 302 is connected so as to be in a feedback loop. Similar to the circuit shown in FIG. 2, the reference voltage V_{ref} output from PTAT circuit 300 may be calculated as follows:

$${V}_{ref} = \frac{{V}_{T} \cdot {log}_{e} n}{{R}_{314}} \cdot m \cdot {R}_{316} ,$$

wherein, according to the Ebers-Moll equation, the thermal voltage V_{T} multiplied by the natural logarithm of the ratio of current densities between transistors 310 and 312 is equivalent to ΔV_{be}.

As noted above, due to temperature increases, a delay output by delay line 108 will increase. However, as shown by the above equations, because reference voltage V_{ref} is dependent on temperature T, reference voltage V_{ref} will increase as the temperature increases, provided that V_{ref} has a positive temperature coefficient. Moreover, consistent with an embodiment of the present invention, reference voltage V_{ref} emitted from PTAT circuit 300 always has a positive temperature coefficient, and therefore an increased V_{ref} will compensate for any delay increases caused by increasing temperature. Delay line circuit 100 using PTAT circuit 300 may thus produce a delay that is independent of temperature effects, as PTAT circuit 300 automatically compensates for any temperature-related delay changes. Moreover, consistent with the present invention, reference voltage V_{ref} may have a high power supply rejection ratio.

Referring back to FIG. 1, regulated voltage Vₒᵤₜ, when using PTAT circuit 300 as voltage generating circuit 102 may be rewritten as:

$${V}_{out} = \frac{{V}_{T} \cdot {log}_{e} n}{{R}_{314}} \cdot m \cdot {R}_{316} \cdot ( 1 + \frac{{R}_{108}}{{R}_{110}} ) .$$

As can be seen by the above equations, reference voltage Vₒᵤₜ may be tuned by choosing the values of ratios n and m, and resistances R₁₀₈, R₁₁₀, R₃₁₄, and R₃₁₆ to output a regulated voltage Vₒᵤₜ, having a specific delay. Accordingly, delay line circuit 100 using PTAT circuit 300 as a reference voltage generating circuit 102 may allow for a highly customizable circuit for generating a delay that automatically compensates for temperature effects.

Accordingly, embodiments consistent with the present invention may provide a delay line circuit which is capable of generating a delay signal that is independent of temperature effects. That is, a delay line circuit consistent with the present invention may automatically compensate for temperature effects. Moreover, embodiments consistent with the present invention may compensate for temperature effects without relying on a reference clock. Therefore, embodiments consistent with the present invention may be able to eliminate the need for a reference clock, allowing for a delay line circuit consistent with the present invention to be integrated into a smaller package, and/or allowing integration into systems and specifications which do not use a reference clock, including, for example, the JEDEC DDR2 and DDR3 standards.

Other embodiments consistent with the present invention will be apparent to those skilled in the art from consideration of the specification and practice of the invention disclosed herein. It is intended that the specification and examples be considered as exemplary only. Accordingly, the invention should only be limited by the following claims.

What is claimed is:

1. A delay line circuit, comprising:
a reference voltage generating circuit that generates a reference voltage, the reference voltage having a positive temperature coefficient;
a voltage regulating circuit that generates a regulated voltage in response to the generated reference voltage as an input; and
a delay chain circuit coupled to the voltage regulator to receive the regulated voltage, the delay chain circuit outputting a delay signal.

2. The delay line circuit of claim 1, wherein the delay signal is independent of a supplied power and a temperature of the circuit.

3. The delay line circuit of claim 1, wherein the delay line circuit does not receive a reference clock signal.

4. The delay line circuit of claim 1, wherein
a change in the delay signal with a temperature of the circuit is compensated, at least partially, by a change in the reference voltage.

5. The delay line circuit of claim 4, wherein the delay time decreases as the regulated voltage increases.

6. The delay line circuit of claim 1, wherein the regulated voltage has a high power supply rejection ratio which is independent of a supplied power.

7. The delay line circuit of claim 1, wherein the reference voltage generating circuit comprises a bandgap reference circuit.

8. The delay line circuit of claim 7, wherein the bandgap reference circuit comprises:
a plurality of current sources, each of the current sources receiving a supply voltage as an input, and each of the current sources outputting a current through a resistance;
a first transistor coupled to a first current source of the plurality of current sources, the first transistor receiving a first current as an input;
a second transistor coupled to a second current source of the plurality of current sources, the second transistor receiving a second current as an input; and
an amplifier coupled to the first and second transistors and the current sources.

9. The delay line circuit of claim 8, wherein
the first transistor has a first base-emitter voltage V_{be1}, the second transistor has a second base-emitter voltage V_{be2}, and a ratio of current between the first transistor and the second transistor is 1:n, n being a positive integer.

10. The delay line circuit of claim 9, further comprising:
a first resistor, having resistance R₁, coupled between the second current source and the second transistor;
a second resistor, having resistant R₂, coupled between the second current source and a base of the second transistor; and
a third resistor, having resistance R₃, coupled between the base of the second resistor and an output of the delay line circuit.

11. The delay line circuit of claim 10, wherein
the plurality of current sources comprises three current sources, including the first current source, the second current source, and a third current source; and
a ratio of currents output from the first current source, the second current source, and the third current source is 1:1:m, m being a positive integer.

12. The delay line circuit of claim 11, wherein
the reference voltage is given by the equation
$${V}_{ref} = ( \frac{{V}_{T} \cdot {log}_{e} n}{{R}_{2}} + \frac{{V}_{be 1}}{{R}_{1}} ) \cdot m \cdot {R}_{3} ,$$
wherein V_{T} is the thermal voltage of the delay line circuit defined as
$${V}_{T} = \frac{kT}{q} ,$$
T being the temperature of the delay line circuit in degrees Kelvin, k being Boltzmann's constant, and q being the charge of an electron.

13. The delay line circuit of claim 12, wherein the values of n, R₂, and R₁ are selected such that
$$\frac{{V}_{T} \cdot {log}_{e} n}{{R}_{2}} > \frac{{V}_{be 1}}{{R}_{1}} ,$$
thereby generating the reference voltage to have a positive temperature coefficient.

14. The delay line circuit of claim 1, wherein the reference voltage generating circuit comprises a proportional to absolute temperature (PTAT) circuit.

15. The delay line circuit of claim 14, wherein the PTAT circuit comprises:
a plurality of current sources, each of the current sources receiving a supply voltage as an input, and each of the current sources outputting a current;
a first transistor coupled to a first current source of the plurality of current sources, the first transistor receiving a first current as an input;
a second transistor coupled to a second current source of the plurality of current sources, the second transistor receiving a second current as an input; and
an amplifier coupled to the first and second transistors and the current sources.

16. The delay line circuit of claim 15, wherein
the first transistor has a first base-emitter voltage V_{be1}, the second transistor has a second base-emitter voltage V_{be2}, and a ratio of current between the first transistor and the second transistor is 1:n, n being a positive integer.

17. The delay line circuit of claim 16, further comprising:
a first resistor, having resistance R₁, coupled between the second current source and the second transistor; and
a second resistor, having resistant R₂, coupled between the second current source and an output of the delay line circuit.

18. The delay line circuit of claim 17, wherein
the plurality of current sources comprises three current sources, including the first current source, the second current source, and a third current source; and
a ratio of currents output from the first current source, the second current source, and the third current source is 1:1:m, m being a positive integer.

19. The delay line circuit of claim 18, wherein
the reference voltage is given by the equation
$${V}_{ref} = \frac{{V}_{T} \cdot {log}_{e} n}{{R}_{1}} \cdot m \cdot {R}_{2} ,$$
wherein V_{T} is the thermal voltage of the delay line circuit defined as
$${V}_{T} = \frac{kT}{q} ,$$
T being the temperature of the delay line circuit in degrees Kelvin, k being Boltzmann's constant, and q being the charge of an electron.

20. A bandgap voltage reference circuit for generating a reference voltage, comprising:
a plurality of current sources, each of the current sources receiving a supply voltage as an input, and each of the current sources outputting a current through a resistance;
a first transistor coupled to a first current source of the plurality of current sources, the first transistor receiving a first current as an input;
a second transistor coupled to a second current source of the plurality of current sources, the second transistor receiving a second current as an input; and
an amplifier coupled to the first and second transistors and the current sources, wherein
the generated reference voltage has a positive temperature coefficient.

21. The bandgap voltage reference circuit of claim 20, wherein
the first transistor has a first base-emitter voltage V_{be1}, the second transistor has a second base-emitter voltage V_{be2}, and a ratio of current between the first transistor and the second transistor is 1:n, n being a positive integer.

22. The bandgap voltage reference circuit of claim 21, further comprising:
a first resistor, having resistance R₁, coupled between the second current source and the second transistor;
a second resistor, having resistant R₂, coupled between the second current source and a base of the second transistor; and
a third resistor, having resistance R₃, coupled between the base of the second resistor and an output of the delay line circuit.

23. The bandgap voltage reference circuit of claim 22, wherein
the plurality of current sources comprises three current sources, including the first current source, the second current source, and a third current source; and
a ratio of currents output from the first current source, the second current source, and the third current source is 1:1:m, m being a positive integer.

24. The bandgap voltage reference circuit of claim 23, wherein
the reference voltage is given by the equation
$${V}_{ref} = ( \frac{{V}_{T} \cdot {log}_{e} n}{{R}_{2}} + \frac{{V}_{be 1}}{{R}_{1}} ) \cdot m \cdot {R}_{3} ,$$
wherein V_{T} is the thermal voltage of the delay line circuit defined as
$${V}_{T} = \frac{kT}{q} ,$$
T being the temperature of the delay line circuit in degrees Kelvin, k being Boltzmann's constant, and q being the charge of an electron.

25. The bandgap voltage reference circuit of claim 24, wherein the values of n, R₁, and R₂ are selected such that
$$\frac{{V}_{T} \cdot {log}_{e} n}{{R}_{2}} > \frac{{V}_{be 1}}{{R}_{1}} ,$$
thereby generating the reference voltage to have a positive temperature coefficient.

26. A proportional to absolute temperature (PTAT) circuit for generating a reference voltage having a positive temperature coefficient, comprising:
a plurality of current sources, each of the current sources receiving a supply voltage as an input, and each of the current sources outputting a current;
a first transistor coupled to a first current source of the plurality of current sources, the first transistor receiving a first current as an input;
a second transistor coupled to a second current source of the plurality of current sources, the second transistor receiving a second current as an input; and
an amplifier coupled to the first and second transistors and the current sources, wherein
the generated reference voltage has a positive temperature coefficient.

27. The PTAT circuit of claim 26, wherein
the first transistor has a first base-emitter voltage V_{be1}, the second transistor has a second base-emitter voltage V_{be2}, and a ratio of current between the first transistor and the second transistor is 1:n, n being a positive integer.

28. The PTAT circuit of claim 27, further comprising:
a first resistor, having resistance R₁, coupled between the second current source and the second transistor; and
a second resistor, having resistant R₂, coupled between the second current source and an output of the delay line circuit.

29. The PTAT circuit of claim 28, wherein
the plurality of current sources comprises three current sources, including the first current source, the second current source, and a third current source; and
a ratio of currents output from the first current source, the second current source, and the third current source is 1:1:m, m being a positive integer.

30. The PTAT circuit of claim 29, wherein
the reference voltage is given by the equation
$${V}_{ref} = \frac{{V}_{T} \cdot {log}_{e} n}{{R}_{1}} \cdot m \cdot {R}_{2} ,$$
wherein V_{T} is the thermal voltage of the delay line circuit defined as
$${V}_{T} = \frac{kT}{q} ,$$
T being the temperature of the delay line circuit in Kelvins, k being Boltzmann's constant, and q being the charge of an electron.

31. A method of fixing a delay signal output from a delay line circuit, comprising:
generating a reference voltage using a voltage generator having a positive temperature coefficient;
supplying the reference voltage to a delay chain, the delay chain outputting a delay signal having a predetermined delay, the predetermined delay being dependent on at least a level of the reference voltage and a temperature of the delay line circuit; and
changing the reference voltage in response to a change in the temperature, such that the changed reference voltage compensates for a change in the delay due to the change in the temperature.

32. The method of claim 31, wherein varying the reference voltage comprises:
tuning the voltage generator to output a voltage which compensates for the change in delay.
